(19) United States
(12) Patent Application Publication
(10) Pub. No.: US 2015/0206778 A1
(43) Pub. Date: Jul. 23, 2015

(54) Microwave Processing Apparatus and Microwave Processing Method

(71) Applicant: TOKYO ELECTRON LIMITED, Tokyo (JP)

(72) Inventor: Kouji SHIMOMURA, Nirasaki City (JP)

(21) Appl. No.: 14/591,214

(22) Filed: Jan. 7, 2015

(30) Foreign Application Priority Data
Jan. 20, 2014 (JP) 2014-007408

(51) Int. Cl. H01L 21/67; H05B 6/64; H01L 21/324; H05B 6/70

(52) U.S. Cl. CPC H01L 21/67115; H05B 6/707; H05B 6/6402; H01L 21/324

(57) ABSTRACT

A microwave processing apparatus for processing a substrate by irradiating a microwave to the substrate includes: a processing container configured to accommodate a substrate; and a microwave introducing device configured to have a microwave source that generates a microwave and introduce the microwave into a microwave radiation space within the processing container. The microwave introducing device includes: a waveguide configured to form a transmission path to guide the microwave into the processing container; a first microwave transmission window interposed between the transmission path and the microwave radiation space; and a second microwave transmission window installed to be closer to the microwave source than the first microwave transmission window, and configured to change a traveling direction of the microwave.

### CROSS-REFERENCE TO RELATED APPLICATION

This application claims the benefit of Japanese Patent Application No. 2014-007408, filed on Jan. 20, 2014, in the Japan Patent Office, the disclosure of which is incorporated herein in its entirety by reference.

### TECHNICAL FIELD

The present disclosure relates to a microwave processing apparatus and method for heating a substrate by introducing microwaves into a processing container.

### BACKGROUND

Microwaves can be used to anneal a substrate such as a semiconductor wafer. Annealing using microwaves has a significant process advantage in that it allows for internal heating, local heating, and selective heating, compared with annealing devices using lamp heating or resistance heating. In order to uniformly heat a substrate using microwaves, it is important to effectively introduce microwaves into a processing container and evenly irradiate the microwaves to the substrate. For example, one type of microwave heat treatment device includes a concave lens for dispersing microwave output from a wave guide. The concave lens is aligned with a central line perpendicular to a main surface of a wafer.

When using a microwave processing apparatus for heat treatment, it is required to maintain a uniform heating temperature within a surface of a substrate. In order to increase uniformity of a heating temperature within a surface of a substrate, it is effective to finely adjust distribution of introduced microwaves within a processing container.

### SUMMARY

Some embodiments of the present disclosure provide a microwave processing apparatus capable of finely adjusting distribution of microwave within a processing container of the microwave processing apparatus.

According to an aspect of the present disclosure, there is provided a microwave processing apparatus for processing a substrate by irradiating a microwave to the substrate, including: a processing container configured to accommodate a substrate; and a microwave introducing device configured to have a microwave source that generates a microwave and introduce the microwave into a microwave radiation space within the processing container. The microwave introducing device includes: a waveguide configured to form a transmission path to guide the microwave into the processing container; a first microwave transmission window interposed between the transmission path and the microwave radiation space; and a second microwave transmission window installed to be closer to the microwave source than the first microwave transmission window, and configured to change a traveling direction of the microwave.

According to another aspect of the present disclosure, there is provided a microwave processing method for processing a substrate using the aforementioned microwave processing apparatus.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view illustrating a schematic configuration of a microwave processing apparatus according to an embodiment of the present disclosure.

FIG. 2 is a plan view illustrating a lower surface of a ceiling part of a processing container illustrated in FIG. 1.

FIG. 3 is an explanatory view illustrating a schematic configuration of a high voltage power supply unit of the microwave processing apparatus illustrated in FIG. 1.

FIG. 4 is a block diagram illustrating a hardware configuration of a controller.

FIG. 5 is a view illustrating a configuration example of a rotary transmission window.

FIG. 6 is a view illustrating a state in which an upper dielectric plate in the state of FIG. 5 has been rotated by 180 degrees.

FIG. 7 is a view illustrating another configuration example of the rotary transmission window.

FIG. 8 is a view illustrating a state in which the upper dielectric plate in the state of FIG. 7 has been rotated by 180 degrees.

FIG. 9 is a view illustrating still another configuration example of the rotary transmission window.

FIG. 10 is a view illustrating a state in which the upper dielectric plate in the state of FIG. 9 has been rotated by 180 degrees.

FIG. 11 is a view illustrating a relationship between a thickness of a dielectric plate and a phase of a microwave.

FIG. 12 is a view illustrating a configuration example of the rotary transmission window of a microwave processing apparatus according to another embodiment of the present disclosure.

FIG. 13 is a view illustrating a state in which an upper dielectric member in the state of FIG. 12 has been rotated by 180 degrees.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

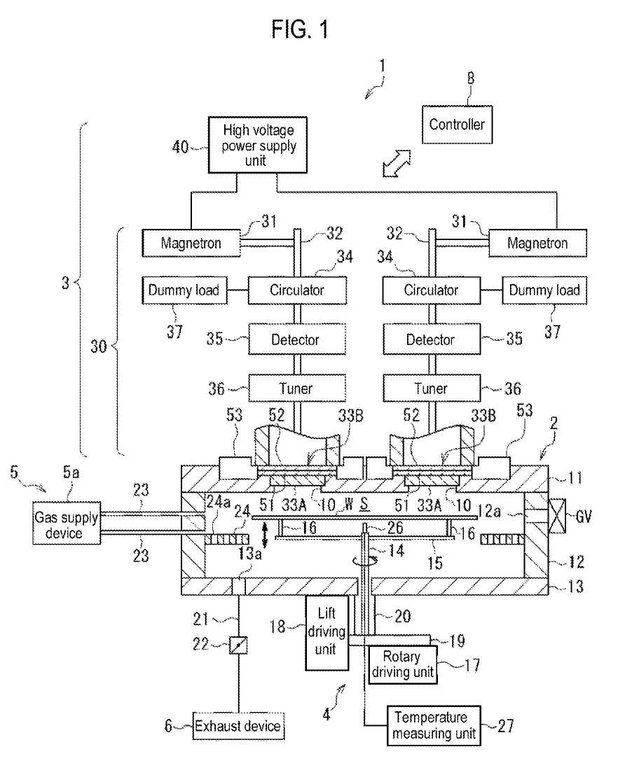

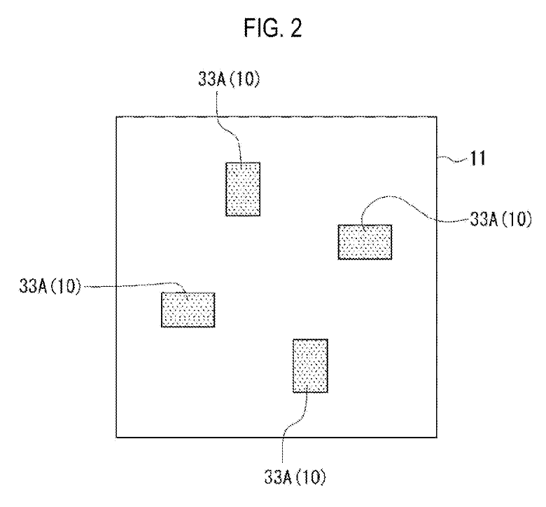

First, a microwave processing apparatus according to a first embodiment of the present disclosure will be described with reference to FIGS. 1 to 11. FIG. 1 is a cross-sectional view illustrating a schematic configuration of a microwave processing apparatus. FIG. 2 is a plan view illustrating a lower surface of a ceiling part of a processing container illustrated in FIG. 1. A microwave processing apparatus 1 is an apparatus for performing an annealing treatment by irradiating microwaves to, for example, a semiconductor wafer W (hereinafter, referred to simply as a “wafer”) used for manufacturing a semiconductor device, according to a plurality of sequential operations. Here, in the wafer W having a flat plate shape, among upper and lower surfaces each having a large area, the upper surface is a surface on which a semiconductor device is to be formed, and this surface will be used as a main surface as a target to be treated.

The microwave processing apparatus 1 includes a processing container 2 for accommodating the wafer W to be processed, a microwave introducing device 3 for introducing microwaves into the processing container 2, a support device 4 for supporting the wafer W within the processing container 2, a gas supply mechanism 5 for supplying a gas into the processing container 2, an exhaust device 6 for vacuum-exhausting the interior of the processing container 2, and a controller 8 for controlling each component of the microwave processing apparatus 1.

### <Processing Container>

The processing container 2 is formed of metal. As a material used to form the processing container 2, for example, aluminum, an aluminum alloy, stainless steel, or the like is used. The microwave introducing device 3 is installed above the processing container 2 and serves as a microwave introducing means for introducing microwaves into the processing container 2. A configuration of the microwave introducing device 3 will be described further down below in detail.

The processing container 2 includes a ceiling part 11 having a plate shape as an upper wall, a bottom part 13 as a lower wall, and four side wall parts 12 as side walls that connect the ceiling part 11 and the bottom part 13. Also, the processing container 2 has a plurality of microwave introducing ports 10 formed to penetrate through the ceiling part 11 vertically, a loading/unloading port 12a formed in one of the side wall parts 12, and an exhaust port 13a formed in the bottom part 13. Here, the four side wall parts 12 form a rectangular cylinder whose horizontal cross-section has right-angled connections. Thus, the processing container 2 has a hollow cubic shape. Also, inner surfaces of all the side wall parts 12 are flat and serve as reflective surfaces for reflecting microwaves. The loading/unloading port 12a serves to allow the wafer W to be loaded from and unloaded to a transfer chamber (not shown) adjacent to the processing container 2 therethrough. A gate valve GV is installed between the processing chamber 2 and the transfer chamber (not shown). The gate valve GV serves to open and close the loading/unloading port 12a. The gate valve GV airtightly seals the processing container 2 in a closed state, and allows for transfer of the wafer W between the processing container 2 and the transfer chamber (not shown) in an open state.

### <Support Device>

The support device 4 includes a tubular shaft 14 penetrating through a substantially central portion of the bottom part 13 of the processing container 2 and extending to the outside of the processing container 2, a plurality of (e.g., three) arm units 15 installed in a substantially horizontal direction from the vicinity of an upper end of the shaft 14, a plurality of support pins 16 detachably installed in each of the arm units 15, a rotary driving unit 17 that rotates the shaft 14, a lift driving unit 18 that moves the shaft 14 up and down, and a movable connecting unit 19 supporting the shaft 14 while connecting the rotary driving unit 17 and the lift driving unit 18. The rotary driving unit 17, the lift driving unit 18, and the movable connecting unit 19 are installed outside of the processing container 2. When the interior of the processing container 2 is made to be in a vacuum, a seal mechanism 20 such as a bellows may be also installed around the portion where the shaft 14 penetrates through the bottom part 13.

In the support device 4, the shaft 14, the arm units 15, the rotary driving unit 17, and the movable connecting unit 19 form a rotary mechanism for horizontally rotating the wafer W supported by the support pin 16. Also, in the support device 4, the shaft 14, the arm units 15, the lift driving unit 18, and the movable connecting unit 19 form a level position adjusting mechanism for adjusting a level position of the wafer W supported by the support pins 16. The plurality of support pins 16 makes contact with a rear surface of the wafer W within the processing container 2 to support the wafer W. The plurality of support pins 16 is installed such that upper end portions thereof are arranged along a circumferential direction of the wafer W. By driving the rotary driving unit 17, the plurality of arm units 15 rotates about the shaft 14, which makes the respective support pins 16 revolve in the horizontal direction. Also, the plurality of support pins 16 and the arm units 15 are configured to be moved in the vertical direction together with the shaft 14 by driving the lift driving unit 18.

The plurality of support pins 16 and the arm units 15 are formed of a dielectric material. As a material used to form the plurality of support pins 16 and the arm units 15, for example, quartz, ceramics, or the like may be used.

The rotary driving unit 17 is not particularly limited as long as it can rotate the shaft 14. For example, the rotary driving unit 17 may have a motor (not shown), or the like. The lift driving unit 18 is not particularly limited as long as it can move up and down the shaft 14 and the movable connecting unit 19. For example, the lift driving unit 18 may have a ball screw (not shown), or the like. The rotary driving unit 17 and the lift driving unit 18 may be an integrated mechanism, or may have a configuration without the movable connecting unit 19. Also, the rotary mechanism for rotating the wafer W in the horizontal direction and the level position adjusting mechanism for adjusting the level position of the wafer W may have any other configuration as long as they can realize respective purposes thereof.

### <Exhaust Mechanism>

The exhaust device 6 includes, for example, a vacuum pump such as a dry pump. The microwave processing apparatus 1 further includes an exhaust pipe 21 connecting the exhaust port 13a and the exhaust device 6 and a pressure adjusting valve 22 installed in the middle of the exhaust pipe 21. The internal space of the processing container 2 is vacuum-exhausted by operating the vacuum pump of the exhaust device 6. Further, the microwave processing apparatus 1 may also perform a processing under atmospheric pressure, and in this case, the vacuum pump is not necessary. Instead of using the vacuum pump such as a dry pump as the exhaust device 6, exhaust equipment installed in facilities where the microwave processing apparatus 1 is installed may also be used.

### <Gas Introducing Mechanism>

The microwave processing apparatus 1 further includes the gas supply mechanism 5 that supplies a gas into the processing container 2. The gas supply mechanism 5 includes a gas supply device 5a having a gas supply source (not shown) and a plurality of pipes 23 (only two pipes are illustrated in FIG. 1) connected to the gas supply device 5a that introduces a processing gas into the processing container 2. The plurality of pipes 23 are connected to the side wall part 12 of the processing container 2.

The gas supply device 5a is configured to supply a gas, for example, N₂, Ar, He, Ne, O₂, or H₂, as a processing gas, into the processing container 2 through the plurality of pipes 23 according to a side flow manner. For the purpose of gas supply into the processing container 2, a gas supply means may be installed, for example, in a position (e.g., the ceiling part 11) facing the wafer W. Alternatively, instead of using the gas supply device 5a, an external gas supply device, which is not included in the configuration of the microwave processing apparatus 1, may be used. Although not shown, the microwave processing apparatus 1 further includes mass flow controllers and opening/closing valves installed in the middle of the pipes 23. Types and flow rates of gases supplied into the processing container 2 are controlled by the mass flow controllers and the shutoff valves.

### <Baffle Plate>

The microwave processing apparatus 1 further includes a frame-shaped baffle plate 24 disposed between the side wall parts 12 and the circumference of the plurality of support pins 16 within the processing container 2. The baffle plate 24 has a plurality of baffle holes 24a formed to penetrate through the baffle plate 24 vertically. The baffle plate 24, while rectifying air in the region within the processing container 2 where the wafer W is to be located, serves to allow the air to flow toward the exhaust port 13a. The baffle plate 24 is formed of metal such as aluminum, an aluminum alloy, or stainless steel, for example. Also, the baffle plate 24 is not essential in the microwave processing apparatus 1 and may not be provided therein.

### <Temperature Measuring Unit>

The microwave processing apparatus 1 further includes a plurality of radiation thermometers 26 for measuring a surface temperature of the wafer W and a temperature measuring unit 27 connected to the plurality of radiation thermometers 26. In FIG. 1, illustration of the plurality of radiation thermometers 26, excluding the radiation thermometer 26 for measuring a surface temperature of a central portion of the wafer W, is omitted.

### <Microwave Radiation Space>

In the microwave processing apparatus 1 according to this embodiment, a microwave radiation space S is located within the processing container 2 defined by the ceiling part 11, the four side wall parts 12 and the baffle plate 24. Microwave is radiated to the microwave radiation space S from the plurality of microwave introducing ports 10, which are through holes formed in the ceiling part 11. Since the ceiling part 11, the four side wall parts 12 and the baffle plate 24 of the processing container 2 are all formed of metal, microwaves are reflected by these components and scattered within the microwave radiation space S. If the baffle plate 24 is not installed, a space within the processing container 2 defined by the ceiling part 11, the four side wall parts 12 and the bottom part 13 forms the microwave radiation space S.

### <Microwave Introducing Device>

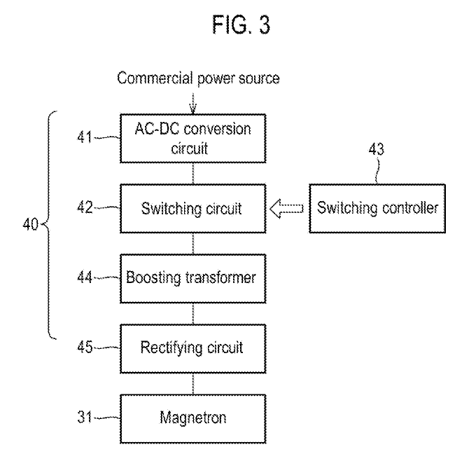

Next, a configuration of the microwave introducing device 3 will be described with reference to FIGS. 1, 2 and 3. FIG. 3 is an explanatory view illustrating a schematic configuration of a high voltage power supply unit of the microwave introducing device 3. As described above, the microwave introducing device 3 is installed above the processing container 2, and serves as a microwave introducing means for introducing electromagnetic waves (microwave) into the processing container 2. As illustrated in FIG. 1, the microwave introducing device 3 includes a plurality of microwave units 30 for introducing microwaves into the processing container 2 and a high voltage power supply unit 40 connected to the plurality of microwave units 30.

### (Microwave Unit)

In this embodiment, the plurality of microwave units 30 has the same configuration. Each of the microwave units 30 includes a magnetron 31 that generates microwaves to process the wafer W, a waveguide 32 that acts as a transmission path to transmit microwaves generated by the magnetron 31 to the processing container 2, a transmission window 33A as a first microwave transmission window fixed to the ceiling part 11 so as to close the microwave introducing ports 10, and a rotary transmission window 33B as a second microwave transmission window installed to be closer to the magnetron 31 than the transmission window 33A. The magnetron 31 corresponds to a microwave source in the present disclosure.

As illustrated in FIG. 2, in this embodiment, the processing container 2 includes four microwave introducing ports 10 formed in the ceiling part 11 at equal intervals along the circumferential direction. Each of the microwave introducing ports 10 has a rectangular shape having longer sides and shorter sides in a plan view. Sizes and ratios between the longer and shorter sides of the microwave introducing ports 10 may differ from each other. However, in terms of increasing uniformity in an annealing treatment on the wafer W and also enhancing controllability, in some embodiments, the four microwave introducing ports 10 may have the same size and shape. Also, in this embodiment, the microwave units 30 are connected to the microwave introducing ports 10, in one-to-one correspondence. That is, the number of the microwave units is 4.

The magnetron 31 includes an anode (not shown) and a cathode (not shown) to which a high voltage supplied by the high voltage power supply unit 40 is applied. Also, a magnetron capable of oscillating microwaves of several frequencies may be used as the magnetron 31. As for microwaves generated by the magnetron 31, an optimal frequency may be selected for each treatment of an object to be processed. For example, in an annealing treatment, microwaves having a high frequency of 2.45 GHz, 5.8 GHz, or the like may be used. In particular, microwaves having a frequency of 5.8 GHz may be used in an annealing treatment.

The waveguide 32 has a square column shape with a rectangular cross-section and extends upward from the upper surface of the ceiling part 11 of the processing container 2. The magnetron 31 is connected to the vicinity of an upper end portion of the waveguide 32. A lower end portion of the waveguide 32 is in proximity to the upper surface of the rotary transmission window 33B. Microwaves generated by the magnetron 31 are introduced into the processing container 2 through the waveguide 32, the rotary transmission window 33B, and the transmission window 33A.

The transmission window 33A is formed of a dielectric material. As a material of the transmission window 33A, for example, quartz, ceramics, or the like may be used. A gap between the transmission window 33A and the ceiling part 11 is airtightly sealed by a seal member (not shown).

The rotary transmission window 33B includes, for example, two sheets of dielectric plates 51 and 52. The rotary transmission window 33B has a structure in which the relatively rotatable two sheets of dielectric plates 51 and 52 are vertically stacked. The lower dielectric plate 51 and the upper dielectric plate 52 may be brought into close contact with each other or may be spaced apart from each other. Each of the dielectric plates 51 and 52 is rotatably installed. More specifically, the dielectric plates 51 and 52 are independently rotatable in a plane perpendicular to the stacking direction thereof by a rotary driving unit 53. In this case, a direction of the rotational axis is identical to a traveling direction of the microwave transmitted through the waveguide 32. A driving mechanism of the rotary driving unit 53 may be, for example, a rack and pinion mechanism or the like. Configuration of the dielectric plates 51 and 52 will be described further down below in detail.

The microwave unit 30 further includes a circulator 34, a detector 35, and a tuner 36 installed in the middle of the waveguide 32, and a dummy load 37 connected to the circulator 34. The circulator 34, the detector 35, and the tuner 36 are installed in this order from the upper end portion side of the waveguide 32. The circulator 34 and the dummy load 37 form an isolator capable of separating a reflected wave from the processing container 2. More specifically, the circulator 34 guides a reflected wave from the processing container 2 to the dummy load 37, and the dummy load 37 converts the reflected wave guided by the circulator 34 into heat.

The detector 35 serves to detect a reflected wave from the processing container 2 in the waveguide 32. The detector 35 is configured as, for example, an impedance monitor, specifically, a standing wave monitor for detecting an electric field of a standing wave in the waveguide 32. The standing wave monitor may be formed by, for example, three pins protruding to an internal space of the waveguide 32. By detecting a location, phase and strength of an electric field of a standing wave by the standing wave monitor, a reflected wave from the processing container 2 may be detected. The detector 35 may be configured by a directional coupler capable of detecting a progressive wave and a reflected wave.

The tuner 36 serves to perform impedance matching (hereinafter, referred to simply as “matching”) between the magnetron 31 and the processing container 2. Matching by the tuner 36 is performed based on a detection result of the reflected wave in the detector 35. The tuner 36 may be configured by a conductive plate (not shown) installed to move into and out of the internal space of the waveguide 32. In this case, by controlling a protruding amount of the conductive plate to the internal space of the waveguide 32, an amount of electric power of the reflected wave may be adjusted to thereby adjust impedance between the magnetron 31 and the processing container 2.

### (High Voltage Power Supply Unit)

The high voltage power supply unit 40 supplies a high voltage that generates microwaves for the magnetron 31. As illustrated in FIG. 3, the high voltage power supply unit 40 includes an AC-DC conversion circuit 41 connected to a commercial power source, a switching circuit 42 connected to the AC-DC conversion circuit 41, a switching controller 43 for controlling an operation of the switching circuit 42, a boosting transformer 44 connected to the switching circuit 42, and a rectifying circuit 45 connected to the boosting transformer 44. The magnetron 31 is connected to the boosting transformer 44 through the rectifying circuit 45.

The AC-DC conversion circuit 41 is a circuit for rectifying an alternating current (AC), e.g., 3-phase 200 V AC, from the commercial power source and converting the same into a direct current (DC) having a predetermined waveform. The switching circuit 42 is a circuit for controlling ON/OFF of the DC converted by the AC-DC conversion circuit 41. The switching circuit 42 performs phase-shifting pulse width modulation (PWM) control or pulse amplitude modulation (PAM) control, under the control of the switching controller 43, to generate a pulse-type voltage waveform. The boosting transformer 44 boosts the voltage waveform output from the switching circuit 42 to a predetermined size. The rectifying circuit 45 is a circuit for rectifying a voltage boosted by the boosting transformer 44 and supplying the rectified voltage to the magnetron 31.

### <Controller>

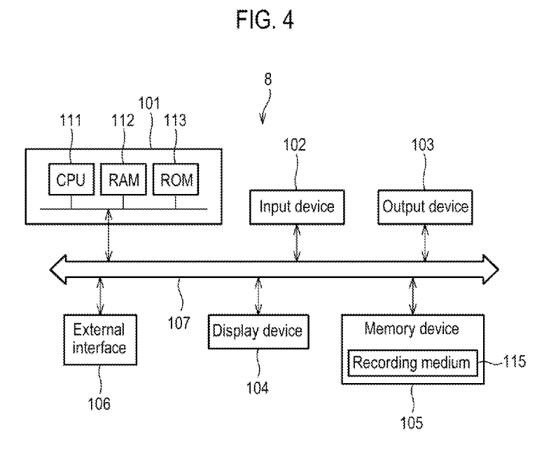

The respective components of the microwave processing apparatus 1 are connected to the controller 8 and controlled by the controller 8. The controller 8 is typically a computer. FIG. 4 illustrates an example of a hardware configuration of the controller 8 illustrated in FIG. 1. The controller 8 includes a main controller 101, an input device 102 such as a keyboard or a mouse, an output device 103 such as a printer, a display device 104, a memory device 105, an external interface 106, and a bus 107 for interconnecting these components. The main controller 101 includes a central processing unit (CPU) 111, a random access memory (RAM) 112, and a read only memory (ROM) 113. The memory device 105 may be, for example, a hard disk device or an optical disk device, but it may have any type of memory as long as it can store information. Further, the memory device 105 writes information in a computer-readable recording medium 115 and also reads information from the recording medium 115. The recording medium 115 may be, for example, a hard disk, an optical disk, a flash memory and the like, but it may be any type of recoding medium as long as it can store information. The recording medium 115 may also be a recording medium that stores a recipe of a microwave processing method according to this embodiment.

In the controller 8, the CPU 111 uses the RAM 112 as a working area and executes a program stored in the ROM 113 or the memory device 105 to thereby execute a heat treatment on the wafer W in the microwave processing apparatus 1 according to this embodiment. Specifically, the controller 8 controls the components of the microwave processing apparatus 1 (e.g., the microwave introducing device 3, the support device 4, the gas supply device 5a, the exhaust device 6, etc.) related to process conditions such as a temperature of the wafer W, a pressure within the processing container 2, a gas flow rate, microwave output, and a rotating speed of the wafer W.

### <Rotary Transmission Window>

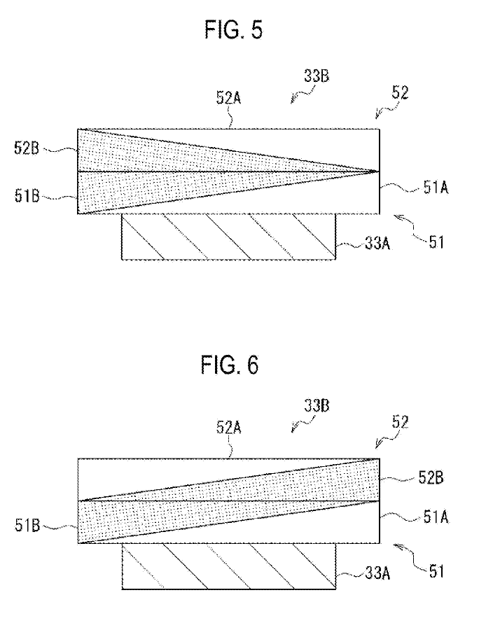

Next, configuration examples of the rotary transmission window 33B used in this embodiment will be described with reference to FIGS. 5 to 10. The rotary transmission window 33B includes two sheets of dielectric plates 51 and 52. The dielectric plates 51 and 52 are configured such that permittivity thereof in a direction perpendicular to the traveling direction of microwaves transmitted through the waveguide 32 is not uniform. As a material of the dielectric plates 51 and 52, in addition to quartz and ceramics, a metal oxide such as alumina (Al₂O₃) or hafnium oxide (HfO₂), a metamaterial, or the like, for example, may be used. If the dielectric plates 51 and 52 are formed of quartz, permittivity thereof may be changed by doping quartz with impurities. For example, if B₂O₃ is used as an impurity, when a dose of B₂O₃ is 35 wt % with respect to quartz having permittivity of 3.81 and dielectric loss of 0.0019 at a frequency of 10 GHz, the permittivity and dielectric loss are changed to 5.06 and 0.034, respectively, at the frequency of 10 GHz. In this case, although the dielectric loss of quartz is increased by about one digit, it is considered that extreme heat is not generated when transmitting microwaves.

FIGS. 5 to 10 show configuration examples of the dielectric plates 51 and 52. FIGS. 5 and 6 illustrate a first example. In FIGS. 5 and 6, the dielectric plate 51 is formed by bonding two wedge-shaped members 51A and 51B having different permittivity from each other. Each of the wedge-shaped members 51A and 51B has a wedge-shaped cross-section having a sloped surface, and the sloped surfaces are bonded to each other. Also, the dielectric plate 52 is formed by bonding two wedge-shaped members 52A and 52B having different permittivity from each other. Each of the wedge-shaped members 52A and 52B has a wedge-shaped cross-section having a sloped surface, and the sloped surfaces are bonded to each other. Here, the wedge-shaped members 51A and 52A have low permittivity, and the wedge-shaped members 51B and 52B have relatively high permittivity to that of the wedge-shaped members 51A and 52A, respectively. In this manner, by bonding two wedge-shaped members having different permittivity from each other, permittivity within each of the dielectric plates 51 and 52 can be made uneven in the direction perpendicular to the traveling direction of the microwave transmitted through the waveguide 32. In this example, the wedge-shaped members 51A and 52A may be formed of quartz and the wedge-shaped members 51B and 52B may be formed of quartz doped with B₂O₃ within a range from 10 to 40 wt %, for example, whereby the distribution of permittivity as illustrated in FIGS. 5 and 6 can be made. In FIGS. 5 and 6, the quartz doped with B₂O₃ is emphatically illustrated to have a dot pattern. Alternatively, in this example, the wedge-shaped members 51A and 52A may be formed of quartz, while the wedge-shaped members 51B and 52B may be formed of a material having high permittivity such as alumina (Al₂O₃) or hafnium oxide (HfO₂).

Further, as illustrated in FIG. 6, by rotating the dielectric plate 52 in the plane perpendicular to the stacking direction, for example, by 180 degrees with respect to the dielectric plate 51 (or by rotating the dielectric plate 51 with respect to the dielectric plate 52), a deflection angle of the microwave transmitting through the rotary transmission window 33B can be changed. In this example, in FIG. 5, a portion of the dielectric plate 51 having high permittivity vertically overlaps with a portion of the dielectric plate 52 having high permittivity, and a portion of the dielectric plate 51 having low permittivity vertically overlaps with a portion of the dielectric plate 52 having low permittivity. Thus, in terms of the entirety of the rotary transmission window 33B, a thickness-considered weighted average of permittivity in the stacking direction of the dielectric plates 51 and 52 is significantly changed in the direction perpendicular to the stacking direction, maximizing a distribution of permittivity. Thus, in FIG. 5, a deflection angle of microwaves that are transmitted through the rotary transmission window 33B is maximized.

On the contrary, in FIG. 6, a portion of the dielectric plate 51 having high permittivity vertically overlaps with a portion of the dielectric plate 52 having low permittivity, and a portion of the dielectric plate 51 having low permittivity vertically overlaps with a portion of the dielectric plate 52 having high permittivity. Thus, in terms of the entirety of the rotary transmission window 33B, a thickness-considered weighted average of permittivity in the stacking direction of the dielectric plates 51 and 52 is substantially uniform in the direction perpendicular to the stacking direction, minimizing a distribution of permittivity. Thus, in FIG. 6, a deflection of microwaves that are transmitted through the rotary transmission window 33B is minimized.

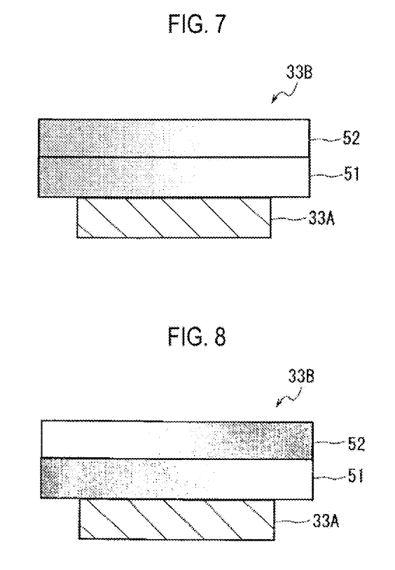

FIGS. 7 and 8 illustrate a second example. In FIGS. 7 and 8, as a material of the dielectric plates 51 and 52 of the rotary transmission window 33B, a material having permittivity which gradually changes in the direction perpendicular to the stacking direction is used. In FIGS. 7 and 8, a change in permittivity is emphatically shown as grayscale gradations. In this example, the dielectric plates 51 and 52 are formed of quartz, and, by continuously changing a dose of B₂O₃ with respect to quartz in the direction perpendicular to the stacking direction, for example, the distribution of permittivity as illustrated in FIGS. 7 and 8 can be obtained.

As illustrated in FIGS. 7 and 8, by rotating the dielectric plate 52 in the plane perpendicular to the stacking direction, for example, by 180 degrees with respect to the dielectric plate 51 (or by rotating the dielectric plate 51 with respect to the dielectric plate 52), a degree of deflection of microwave that transmits through the rotary transmission window 33B can be changed. In this example, in FIG. 7, a portion of the dielectric plate 51 having high permittivity vertically overlaps with a portion of the dielectric plate 52 having high permittivity, and a portion of the dielectric plate 51 having low permittivity vertically overlaps with a portion of the dielectric plate 52 having low permittivity. Thus, in terms of the entirety of the rotary transmission window 33B, a thickness-considered weighted average of permittivity in the stacking direction of the dielectric plates 51 and 52 are significantly changed in the direction perpendicular to the stacking direction, maximizing a distribution of permittivity. Thus, in FIG. 7, deflection of microwaves that are transmitted through the rotary transmission window 33B is maximized.

On the contrary, in FIG. 8, a portion of the dielectric plate 51 having high permittivity vertically overlaps with a portion of the dielectric plate 52 having low permittivity, and a portion of the dielectric plate 51 having low permittivity vertically overlaps with a portion of the dielectric plate 52 having high permittivity. Thus, in terms of the entirety of the rotary transmission window 33B, a thickness-considered weighted average of permittivity in the stacking direction of the dielectric plates 51 and 52 are substantially uniform in the direction perpendicular to the stacking direction, minimizing a distribution of permittivity. Thus, in FIG. 8, deflection of microwaves that are transmitted through the rotary transmission window 33B is Minimized.

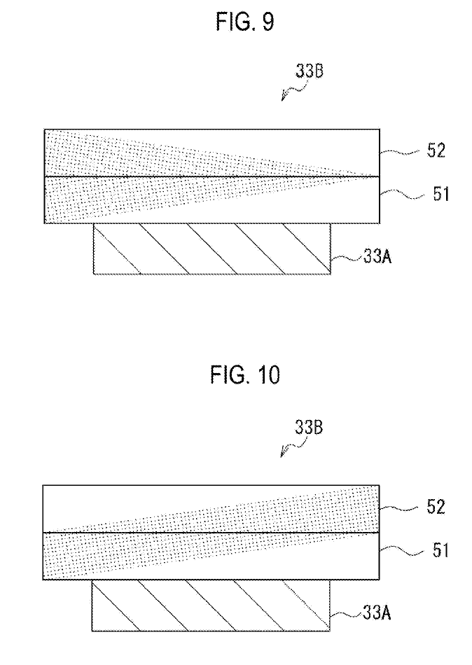

FIGS. 9 and 10 illustrate a third example. FIGS. 9 and 10 illustrate an example of using metamaterial having arbitrarily-adjustable permittivity. Here, a ratio between a portion having high permittivity and a portion having low permittivity in each of the dielectric plates 51 and 52 are changed in a thickness direction thereof (i.e., in the traveling direction of the microwave transmitted through the waveguide 32). In FIGS. 9 and 10, in each of the dielectric plates 51 and 52, a portion having relatively high permittivity is indicated as a dot pattern, and a portion having low permittivity is indicated as a white color. Also, as illustrated in FIGS. 9 and 10, by rotating the dielectric plate 52 in the plane perpendicular to the stacking direction, for example, by 180 degrees with respect to the dielectric plate 51 (or by rotating the dielectric plate 51 with respect to the dielectric plate 52), a degree of deflection of microwave that transmits through the rotary transmission window 33B can be changed. In this example, in FIG. 9, a portion of the dielectric plate 51 having high permittivity vertically overlaps with a portion of the dielectric plate 52 having high permittivity, and a portion of the dielectric plate 51 having low permittivity vertically overlaps with a portion of the dielectric plate 52 having low permittivity. Thus, in terms of the entirety of the rotary transmission window 33B, a thickness-considered weighted average of permittivity in the stacking direction of the dielectric plates 51 and 52 are significantly changed in the direction perpendicular to the stacking direction, maximizing a distribution of permittivity. Thus, in FIG. 9, deflection of microwaves that are transmitted through the rotary transmission window 33B is maximized.

On the contrary, in FIG. 10, a portion of the dielectric plate 51 having high permittivity vertically overlaps with a portion of the dielectric plate 52 having low permittivity, and a portion of the dielectric plate 51 having low permittivity vertically overlaps with a portion of the dielectric plate 52 having high permittivity. Thus, in terms of the entirety of the rotary transmission window 33B, a thickness-considered weighted average of permittivity in the stacking direction of the dielectric plates 51 and 52 are substantially uniform in the direction perpendicular to the stacking direction, minimizing a distribution of permittivity. Thus, in FIG. 10, deflection of microwaves that are transmitted through the rotary transmission window 33B is minimized.

Also, by using a metamaterial, the dielectric plates 51 and 52 may be configured such that permittivity thereof is gradually changed in the direction perpendicular to the stacking direction, respectively, like the cases of FIGS. 7 and 8.

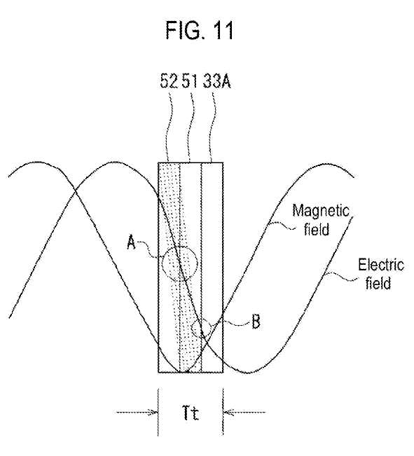

Here, a relationship between a thickness of a dielectric plate and a phase of microwave will be described with reference to FIG. 11. As illustrated in FIGS. 5 to 10, if two or more sheets of dielectric plates are stacked, a thickness of the dielectric plates may be determined in consideration of a wavelength of microwave induced by the waveguide 32 such that plasma (abnormal discharge) is not generated in a stacking boundary. For example, in some embodiments, a total thickness Tt of the transmission window 33A and the rotary transmission window 33B may be 0.25λ/εr or smaller (where λ is a wavelength of microwave induced by the waveguide 32, and εr is relative permittivity of the dielectrics forming the transmission window 33A and the rotary transmission window 33B). In this manner, in the stacking boundaries between the transmission window 33A and the dielectric plate 51 and between the dielectric plate 51 and the dielectric plate 52, for example, as shown in the encircled portions “A” and “B” in FIG. 11, an electric field generated by microwaves may be adjusted to a minimum value or to a value close to the minimum value. Thus, generation of plasma in the stacking boundaries can be suppressed.

Further, in some embodiments, if it is difficult to set the total thickness Tt of the transmission window 33A and the rotary transmission window 33B to 0.25λ/εr or smaller, a thickness t of each sheet of dielectric forming the transmission window 33A and the rotary transmission window 33B may be set to (n−0.125)λ/εr≦t≦(n+0.125)λ/εr (where λ and εr denote the same as mentioned above and n is a positive integer) such that plasma is not generated in the stacking boundaries.

Further, the present disclosure is not limited to the case of stacking two sheets of dielectric plates. That is, only one dielectric plate may be provided, or three or more dielectric plates may be stacked. In addition, a rotational angle of the dielectric plates may be arbitrarily determined within a range from 0 to 360 degrees, without being limited to 180 degrees as illustrated above.

As described above, in the microwave processing apparatus 1, the rotary transmission window 33B includes the dielectric plates 51 and 52 having permittivity which is not uniform in the direction perpendicular to the traveling direction of the microwave transmitted through the waveguide 32. Also, in the microwave processing apparatus 1, by rotating any one or both of the dielectric plates 51 and 52 by a certain angle in a plane perpendicular to the stacking direction, the traveling direction of microwave that transmits through the rotary transmission window 33B may be changed to thereby adjust an electric field strength distribution in the microwave radiation space S within the processing container 2. Thus, in the microwave processing apparatus 1, unevenness of heating temperatures within the plane of the wafer W can be suppressed by the rotary transmission window 33B, thus performing a uniform annealing treatment within the plane of the wafer W.

### [Microwave Processing Method]

Next, a microwave processing method performed in the microwave processing apparatus 1 will be described. First, a command is input from the input device 102 of the controller 8 to perform an annealing treatment in the microwave processing apparatus 1. Thereafter, upon receipt of the command, the main controller 101 reads a recipe stored in the memory device 105 or the computer-readable recording medium 115. Subsequently, a control signal is transmitted from the main controller 101 to each of the end devices (for example, the microwave introducing device 3, the support device 4, the gas supply device 5a, the exhaust device 6, etc.) of the microwave processing apparatus 1, so that the annealing treatment may be executed under conditions based on the recipe.

Thereafter, the gate valve GV is opened, and the wafer W is loaded into the processing container 2 through the gate valve GV and the loading/unloading port 12a by a transfer device (not shown) and placed on the plurality of support pins 16. And then, the plurality of support pins 16 for supporting the wafer W is moved vertically by the lift driving unit 18 of the support device 4 so as to be set to a predetermined level position.

Thereafter, the gate valve GV is closed, and if necessary, the interior of the processing container 2 is vacuum-evacuated by the exhaust device 6. If necessary, a processing gas is introduced into the processing container 2 by the gas supply device 5a. The internal space of the processing container 2 is adjusted to be a predetermined pressure by adjusting an air exhaust amount and a supply amount of the processing gas. If necessary, the wafer W is rotated at a predetermined speed in the horizontal direction by driving the rotary driving unit 17 under the control of the controller 8. Also, the rotation of the wafer W may be discontinuous, rather than being continuous.

Thereafter, a voltage is applied from the high voltage power supply unit 40 to the magnetron 31 to generate microwaves. Microwaves generated by the magnetron 31 propagate through the waveguide 32, are transmitted through the rotary transmission window 33B and the transmission window 33A, and are introduced to a space above the wafer W within the processing container 2. In this embodiment, a plurality of magnetrons 31 sequentially generates microwaves, and the microwaves are alternately introduced into the processing container 2 from each of microwave introducing ports 10. In this embodiment, before microwaves are introduced or while microwaves are being introduced, the dielectric plate 51 and/or 52 of the rotary transmission window 33B is rotated to change a deflection angle of the microwaves, whereby a distribution of microwaves may be finely controlled in the microwave radiation space S. Further, in a case in which the wafer W is processed by rotating the dielectric plate 51 and/or 52 of the rotary transmission window 33B while microwaves are being introduced, the dielectric plate 51 and/or 52 may be intermittently rotated at certain intervals or continuously rotated. By rotating the dielectric plate 51 and/or 52 of the rotary transmission window 33B in this manner, positions of nodes and anti-nodes of a standing wave of the microwaves can be changed in the microwave radiation space S, whereby the wafer W may be uniformly processed within the plane. Also, the plurality of magnetron 31 may simultaneously generate a plurality of microwaves and the microwaves may be simultaneously introduced from the respective microwave introducing ports 10 into the processing container 2.

The microwaves introduced into the processing container 2 are irradiated to the wafer W, and the wafer W is rapidly heated by electromagnetic wave heating such as joule-heating, magnetic heating, or induction heating. As a result, an annealing treatment is performed on the wafer W.

During the annealing treatment, the wafer W may be rotated to reduce deflection of microwaves irradiated to the wafer W, thus making a heating temperature within the plane of the wafer W uniform.

When a control signal for terminating the annealing treatment is transmitted from the main controller 101 to each of the end devices of the microwave processing apparatus 1, generation of microwaves is stopped, rotation of the wafer W is stopped, supply of the treatment gas is stopped, and thus the annealing treatment on the wafer W is terminated.

After the annealing treatment for a predetermined period of time or a cooling treatment after the annealing treatment is terminated, the gate valve GV is opened, a level position of the wafer W is adjusted by the support device 4, and the wafer W is then unloaded by the transfer device (not shown).

In the process of manufacturing a semiconductor device, for example, the microwave processing apparatus 1 may be desirably used for the purpose of an annealing treatment for activating doping atoms implanted in a diffusion layer, or the like.

As described above, in the microwave processing apparatus 1 according to this embodiment, a distribution of microwaves in the processing container 2 can be finely adjusted, and thus the wafer W can be uniformly heated within the plane thereof.

### Second Embodiment

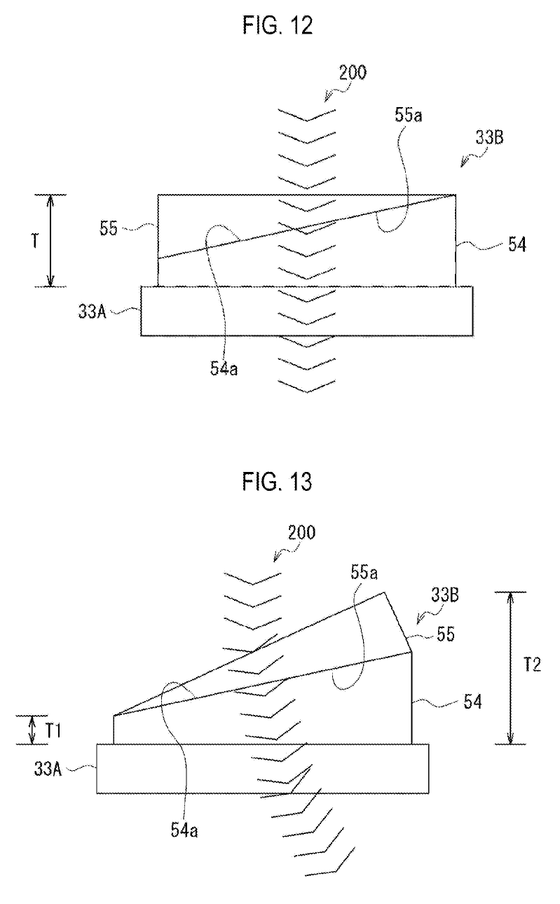

Next, a microwave processing apparatus according to a second embodiment of the present disclosure will be described with reference to FIGS. 12 and 13. The microwave processing apparatus according to this embodiment is different from the microwave processing apparatus 1 of the first embedment, in a configuration of a rotary transmission window. Hereinafter, only the difference of the microwave processing apparatus according to this embodiment from the microwave processing apparatus 1 of the first embodiment will be described and descriptions of the same components as those of the first embodiment will be omitted.

As illustrated in FIGS. 12 and 13, in this embodiment, a rotary transmission window 33B includes, for example, two dielectric members 54 and 55 which are rotatable with respect to each other. The dielectric members 54 and 55 may be formed of the same material or may be formed of different materials. As a material of the dielectric members 54 and 55, in addition to quartz and ceramic, for example, a metal oxide such as alumina (Al₂O₃) or hafnium oxide (HfO₂), a metamaterial, and the like may be used.

The dielectric members 54 and 55 have a configuration in which thicknesses thereof are changed in a traveling direction of a microwave 200 transmitted through the waveguide 32. Specifically, the dielectric member 54 has a sloped surface 54a and has a wedge-shaped cross-section, and the dielectric member 55 has a sloped surface 55a and has a wedge-shaped cross-section. The rotary transmission window 33B has a structure in which the two dielectric members 54 and 55 vertically overlap such that the sloped surfaces 54a and 55a thereof face each other. The lower dielectric member 54 and the upper dielectric member 55 may be brought into close contact with each other or may be spaced apart from one another.

Each of the dielectric members 54 and 55 is rotatably installed. That is, the dielectric members 54 and 55 are configured to be rotated about independent and different rotational shafts, respectively, by the rotary driving unit 53 (see FIG. 1). A driving mechanism of the rotary driving unit 53 may be, for example, a rack and pinion mechanism, or the like.

When only the upper dielectric member 55 is rotated, for example, by about 180 degrees from the state of FIG. 12 by the rotary driving unit 53, the state illustrated in FIG. 13 comes. In the state illustrated in FIG. 12, in terms of the entirety of the rotary transmission window 33B, the thickness T is substantially uniform in the direction perpendicular to the stacking direction of the dielectric members 54 and 55. On the contrary, in FIG. 13, portions having the minimum thicknesses in the dielectric member 54 and the dielectric member 55, which have the wedge-shaped cross-section, vertically overlap with each other, and portions having the maximum thicknesses in the dielectric member 54 and the dielectric member 55 vertically overlap with each other. Thus, in terms of the entirety of the rotary transmission window 33B, a portion having the minimum thickness T1 and a portion having the maximum thickness T2 are formed.

In this embodiment, in FIG. 12, the thickness T of the entire rotary transmission window 33B is uniform and an incident angle of the microwave 200 with respect to the upper surface of the dielectric member 55 is substantially a right angle. Thus, in the state of FIG. 12, a refraction angle of the microwave 200 made incident to the rotary transmission window 33B is zero and a traveling direction of the microwave 200 is not changed.

On the contrary, in the state of FIG. 13, in terms of the entirety of the rotary transmission window 33B, the minimum thickness T1 and the maximum thickness T2 are formed, and the upper surface of the dielectric member 55 is at a sloped angle with respect to the traveling direction of the microwave 200 transmitted through the waveguide 32. Since Snell's law is established between a refraction angle and an incident angle, refraction is increased in the state of FIG. 13, relative to the state of FIG. 12, increasing a change in the traveling direction of the microwave 200.

As described above, in the microwave processing apparatus according to this embodiment, the rotary transmission window 33B includes the dielectric members 54 and 55 having a configuration in which thicknesses thereof are changed, and thus, by rotating any one or both of the dielectric members 54 and 55 by a predetermined angle, a certain incident angle, rather than a right angle, may be formed with respect to the microwave 200 transmitted in the waveguide 32. By doing so, a distribution of electric field strength in the microwave radiation space S within the processing container 2 may be adjusted by changing a traveling direction of the microwave 200 that transmits through the rotary transmission window 33B. Thus, in the microwave processing apparatus of this embodiment, unevenness in heating temperatures within the plane of the wafer W can be suppressed by the rotary transmission window 33B, thus performing a uniform annealing treatment within the plane of the wafer W.

Other configurations and effects of this embodiment are identical to those of the first embodiment.

Further, the present disclosure is not limited to the foregoing embodiments and may be variously modified. For example, the microwave processing apparatus according to the present disclosure is not limited to the case in which a semiconductor wafer is used as a substrate, and may also be applied to, for example, a microwave processing apparatus in which a substrate of a solar battery panel or a substrate for a flat panel display is used as a substrate.

Also, in the microwave processing apparatus, the number of microwave units 30 (the number of magnetrons 31) or the number of microwave introducing ports 10 are not limited to the number mentioned in the foregoing embodiments.

According to the present disclosure in some embodiments, since the microwave processing apparatus includes the second microwave transmission windows for changing a traveling direction of microwaves, it is possible to finely adjust a distribution of electric field strength in a microwave radiation space within the processing container. Thus, according to the microwave processing apparatus of the present disclosure, the wafer W can be uniformly heated within the plane thereof.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A microwave processing apparatus for processing a substrate by irradiating a microwave to the substrate, comprising:
a processing container configured to accommodate a substrate; and
a microwave introducing device configured to have a microwave source that generates a microwave and introduce the microwave into a microwave radiation space within the processing container,
wherein the microwave introducing device comprises:
a waveguide configured to form a transmission path to guide the microwave into the processing container;
a first microwave transmission window interposed between the transmission path and the microwave radiation space; and
a second microwave transmission window installed to be closer to the microwave source than the first microwave transmission window, and configured to change a traveling direction of the microwave.

2. The microwave processing apparatus of claim 1, wherein the second microwave transmission window includes one or more dielectric plates, and wherein permittivity within each of the dielectric plates is not uniform.

3. The microwave processing apparatus of claim 2, wherein the permittivity within each of the dielectric plates is not uniform in a direction perpendicular to the traveling direction of the microwave transmitted through the waveguide.

4. The microwave processing apparatus of claim 2, wherein the second microwave transmission window has a stacked structure of the dielectric plates.

5. The microwave processing apparatus of claim 4, wherein each of the dielectric plates of the second microwave transmission window is rotatably installed.

6. The microwave processing apparatus of claim 1, wherein the second microwave transmission window includes one or more dielectric members, each of the dielectric members having a configuration in which thicknesses thereof are changed, and forms an incident angle, rather than a right angle, with respect to the traveling direction of the microwave transmitted through the waveguide.

7. The microwave processing apparatus of claim 6, wherein each of the dielectric members has a wedge-shaped cross-section along the traveling direction of the microwave.

8. The microwave processing apparatus of claim 6, wherein the second microwave transmission window has a stacked structure of the dielectric members.

9. The microwave processing apparatus of claim 8, wherein each of the dielectric members is rotatably installed.

10. A microwave processing method for processing a substrate using the microwave processing apparatus as set forth in claim 1.
